(19) United States
(12) Patent Application Publication
(10) Pub. No.: US 2005/0156315 A1
(43) Pub. Date: Jul. 21, 2005

(54) Thin films, structures having thin films, and methods of forming thin films

(76) Inventors: Eal H. Lee, Milpitas, CA (US); Michael E. Thomas, Milpitas, CA (US)

Correspondence Address: Honeywell International, 101 Columbia Road, Morristown, NJ, 07962, US

(21) Appl. No.: 10/502,232

(22) PCT Filed: Jan. 24, 2003
(86) PCT No.: PCT/US03/02106

Related U.S. Application Data
(60) Provisional application No. 60/351,644, filed on Jan. 24, 2002.

(51) Int. Cl. H01L 21/4763; H01L 23/48; H01L 29/40

(52) U.S. Cl. 257/751; 257/763; 438/685; 438/643

(57) ABSTRACT

The invention described herein relates to new titanium-comprising materials which can be utilized for forming titanium alloy barrier layers for Cu applications. Titanium alloy sputtering targets can be reactively sputtered in a nitrogen-comprising sputtering gas atmosphere to from titanium alloy nitride film, or alternatively in a nitrogen-comprising and oxygen-comprising atmosphere to form titanium alloy oxygen nitrogen thin film. The thin films formed in accordance with the present invention can contain a non-columnar grain structure, low electrical resistivity, high chemical stability, and barrier layer properties comparable or exceeding those of TaN.

### TECHNICAL FIELD

The invention pertains to titanium alloy thin films with improved copper diffusion barrier properties. The invention also pertains to diffusion protected surfaces and structures containing titanium alloy thin films. The invention additionally pertains to methods of forming barrier layers and methods of forming structures containing barrier layers.

### BACKGROUND OF THE INVENTION

Integrated circuit interconnect technology is changing from aluminum subtractive processes to copper dual damascene processes. The shift from aluminum and its alloys to copper and its alloys is causing new barrier layer materials, specifically TaN, to be developed. TiN films, which were used in aluminum technologies, could be formed by, for example, reactively sputtering a titanium target in a nitrogen-comprising sputtering gas atmosphere. TiN films are reportedly poor barrier layers relative to copper in comparison to TaN.

The problems associated with TiN barrier layers are described with reference to FIGS. 1 and 2. Specifically, FIG. 1 illustrates a preferred barrier layer construction, and FIG. 2 illustrates problems associated with TiN barrier layers.

Referring initially to FIG. 1, a semiconductor wafer fragment 10 is illustrated. Wafer fragment 10 comprises a substrate 12 which can comprise, for example, monocrystalline silicon. To aid in interpretation of the claims that follow, the terms “semiconductive substrate” and “semiconductor substrate” are defined to mean any construction comprising semiconductive material, including, but not limited to, bulk semiconductive materials such as a semiconductive wafer (either alone or in assemblies comprising other materials thereon), and semiconductive material layers (either alone or in assemblies comprising other materials). The term “substrate” refers to any supporting structure, including, but not limited to, the semiconductive substrates described above.

An insulative layer 14 is formed over substrate 12. Insulative layer 14 can comprise, for example, silicon dioxide or borophosphosilicate glass (BPSG). Alternatively, layer 14 can comprise fluorinated silicon dioxide having a dielectric constant less than or equal to 3.7, or a so-called “low-k” dielectric material. In particular embodiments, layer 14 can comprise an insulative material having a dielectric constant less than or equal to 3.0.

A barrier layer 16 is formed to extend within a trench in insulative material 14, and a copper-containing seed layer 18 is formed on barrier layer 16. Copper-containing seed layer 18 can be formed by, for example, sputter deposition from a high purity copper target, with the term “high purity” referring to a target having at least 99.995% purity (i.e., 4N5 purity). A copper-containing material 20 is formed over copper-containing seed layer 18, and can be formed by, for example, electrochemical deposition onto seed layer 18. Copper-containing material 20 and seed layer 18 can together be referred to as a copper-based layer or copper-based mass.

Barrier layer 16 is provided to prevent copper diffusion from materials 18 and 20 into insulative material 14. It has been reported that prior art titanium materials are not suitable as barrier layers for preventing diffusion of copper. Problems associated with prior art titanium-comprising materials are described with reference to FIG. 2, which shows the construction 10 of FIG. 1, but which is modified to illustrate specific problems that can occur if either pure titanium or titanium nitride are utilized as barrier layer 16. Specifically, FIG. 2 shows channels 22 extending through barrier layer 16. Channels 22 can result from columnar grain growth associated with the titanium materials of barrier layer 16. Channels 22 effectively provide paths for copper diffusion through a titanium-comprising barrier layer 16 and into insulative material 14. The columnar grain growth can occur during formation of a Ti or TiN layer 16, or during high temperature processing subsequent to the deposition. Specifically, it is found that even when prior art titanium materials are deposited without columnar grain, the materials can fail at temperatures in excess of 450° C.

In an effort to avoid the problems described with reference to FIG. 2, there has been a development of non-titanium barrier materials for diffusion layer 16. Among the materials which have been developed is tantalum nitride (TaN). It is found that TaN can have a close to nanometer-sized grain structure and good chemical stability as a barrier layer for preventing copper diffusion. However, a difficulty associated with TaN is that the high cost of tantalum can make it difficult to economically incorporate TaN layers into semiconductor fabrication processes. Alternatively, we have found that many titanium alloys can have superior mechanical properties compared to tantalum; both in the sputtering target and sputtered film; thus making them suitable for high-power applications.

Titanium alloys are a lower cost material than tantalum. Accordingly, it is possible to reduce materials cost for the microelectronics industry relative to utilization of copper interconnect technology if methodology could be developed for utilizing titanium-comprising materials, instead of tantalum-comprising materials, as barrier layers for inhibiting copper diffusion. It is therefore desirable to develop new titanium-comprising materials which are suitable as barrier layers for impeding or preventing copper diffusion. The titanium comprising materials can be of any purity, but are preferably high purity; with the term “high purity” referring to a target having at least 99.95% purity (i.e., 3N5 purity).

### SUMMARY OF THE INVENTION

The invention described herein relates to new titanium-comprising materials which can be utilized for forming titanium alloy sputtering targets. These sputtering targets can be used to replace tantalum-comprising targets due to their high-strength and resulting film properties. Specifically, in certain embodiments, the titanium alloy, sputtering targets can be used to form barrier layers for Cu applications. The titanium alloy sputtering targets can be reactively sputtered in a nitrogen-comprising sputtering gas atmosphere to form titanium alloy nitride film, or alternatively. in a nitrogen-comprising and oxygen-comprising atmosphere to form titanium alloy oxygen nitrogen thin film. The thin films formed in accordance with the present invention can contain a non-columnar grain structure, low electrical resistivity, high chemical stability, and barrier layer properties comparable or exceeding those of TaN. Further, the titanium alloy sputtering target materials for production if thin films in accordance with the present invention are more cost-effective for'semiconductor applications than are high-purity tantalum materials.

In one aspect, the invention encompasses a thin film comprising zirconium and nitrogen. At least a portion of the thin film has a non-columnar grain structure.

In one aspect, the invention encompasses a copper barrier film that has a first portion which comprises a non-columnar grain structure and has a second portion that contains columnar grain structure. The film has a substantial absence of amorphous phase material.

In one aspect, the invention encompasses a structure which includes a silicon substrate. The structure has an insulative material over the substrate and a barrier layer comprising (TiZr)ₓN_{z} over the insulative material. The barrier layer has a substantial absence of amorphous structure and at least a portion of the barrier layer contains non-columnar grain structure. The structure also has a layer containing a metal over the barrier layer.

In one aspect, the invention encompasses a method of forming a barrier layer which includes providing a substrate which contains a material to be protected. A titanium material target is provided and material from the target is ablated onto the substrate in the presence of an Ar/N₂ plasma, at a deposition power of from about 1 kW to about 9 kW. The ablated material forms a barrier layer containing titanium and nitrogen which has a substantially uniform thickness over at least a portion of the material to be protected.

In one aspect, the invention encompasses a method of inhibiting copper diffusion into a substrate. A first layer comprising titanium and one or more alloying elements is formed over the substrate. A group of appropriate alloying elements includes Al, Ba, Be, Ca, Ce, Cs, Hf, La, Mg, Nd, Sc, Sr, Y, Mn, V, Si, Fe, Co, Ni, B, C, La, Pr, P, S, Sm, Gd, Dy, Zr, Ho, Er, Yb, W, Cr, Mo, Nb, and Ta. A copper-based layer is then formed over the first layer and separated from the substrate by the first layer. The first layer inhibits copper diffusion from the copper-based layer to the substrate.

For purposes of interpreting this disclosure and the claims that follow, a “titanium-based” material is defined as a material in which titanium is a majority element, and an “alloying element” is defined as an element that is not a majority element in a particular material. A “majority element” is defined as an element which is present in larger concentration than any other element of a material. A majority element can be a predominate element of a material, but can also be present as less than 50% of a material. For instance, titanium can be a majority element of a material in which the titanium is present to only 30%, provided that no other element is present in the material to a concentration of greater than or equal to 30%. The other elements present to concentrations of less than or equal to 30% would be “alloying elements.” . Frequently, titanium-based materials described herein will contain alloying elements at concentrations of from 0.001 atom % to 50 atom %. The percentages and concentrations referred to herein are atom percentages and concentrations, except, of course, for any concentrations and percentages specifically indicated to be other than atom percentages or concentrations.

Additionally, for purposes of interpreting this disclosure and the claims that follow a “copper-based” material is defined as a material in which copper is the majority element.

### BRIEF DESCRIPTION OF THE DRAWINGS

Preferred embodiments of the invention are described below with reference to the following accompanying drawings.

FIG. 1 is a diagrammatic, cross-sectional view of a prior art semiconductor wafer fragment illustrating a conductive copper material separated from an insulative material by a barrier layer.

FIG. 2 is a view of the FIG. 1 prior art wafer fragment illustrating problems which can occur when utilizing prior art Ti-containing materials as the barrier layer.

FIG. 3 is a diagrammatic, cross-sectional view of a semiconductor wafer fragment at a preliminary step of a method of the present invention.

FIG. 4 is a view of the FIG. 3 wafer fragment shown at a processing step subsequent to that of FIG. 3.

FIG. 5 shows the step coverage of a (TiZr)ₓN_{z} liner (Panel A) and the step coverage of a (TiZr)ₓN_{z} liner plus a copper seed coat (Panel B).

FIG. 6 is a view of the FIG. 3 wafer fragment shown at a processing step subsequent to that of FIG. 4.

FIG. 7 is a view of the FIG. 3 wafer fragment shown at a processing step subsequent to that of FIG. 6.

FIG. 8. is a chart showing improvements in mechanical properties of Ti—Zr alloys in comparison to prior art Ta.

FIG. 9 is a graph illustrating a Rutherford Back-scattering Spectroscopy (RBS) profile of as-deposited Ti_{0.45}Zr_{0.024}N_{0.52}.

FIG. 10 is a graph illustrating a Rutherford Back-scattering Spectroscopy profile Ti_{0.45}Zr_{0.024}N_{0.52} after vacuum annealing for 1 hour at from 450° C. to 700° C.

FIG. 11 is a graph illustrating a Rutherford Back-scattering Spectroscopy profile of a TiZrN thin film after stripping Cu layer from a wafer. The TiZrN thin film and Cu layer being initially part of a structure formed in accordance with an exemplary method of the present invention. The illustrated data shows no apparent diffusion of Cu into the TiZrN layer after 5 hours at 700° C.

FIG. 12 shows a SEM microscopy image of a TaN film (Panel A) and a (TiZr)ₓN_{z} film deposited at 400° C. with 6.5 kW power in an Ar/N₂ plasma.

FIG. 13 shows a cross sectional TEM image of a 5 nm (TiZr)ₓN_{z} barrier layer after annealing for 1 hour at 650° C.

FIG. 14 is a graph illustrating the electrical resistivity as a function of deposition power for TaN and (TiZr)ₓN_{z} films deposited at 400° C.

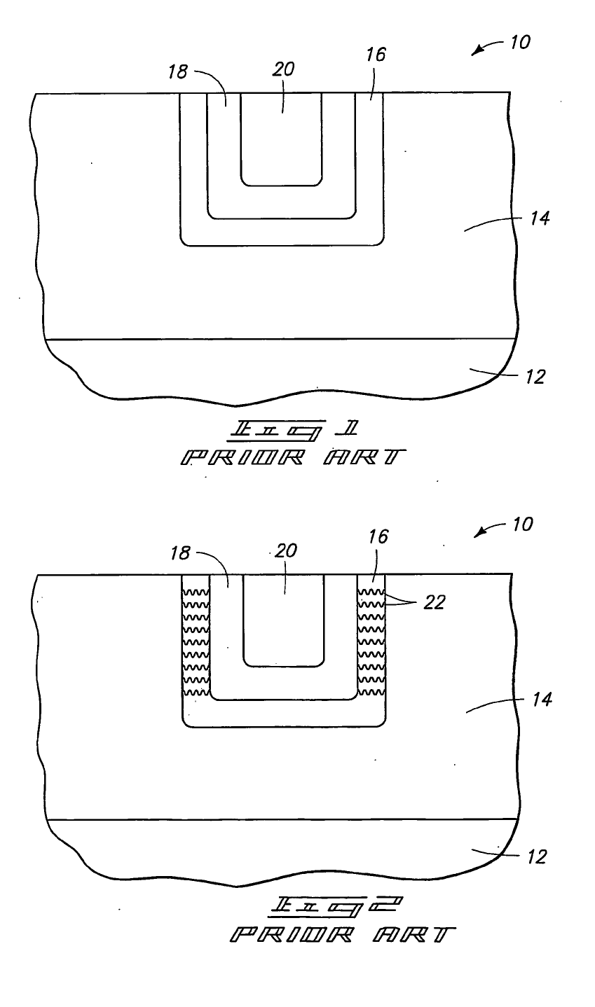

### DETAILED DESCRIPTION OF THE PREFERRED EMBODIMENTS

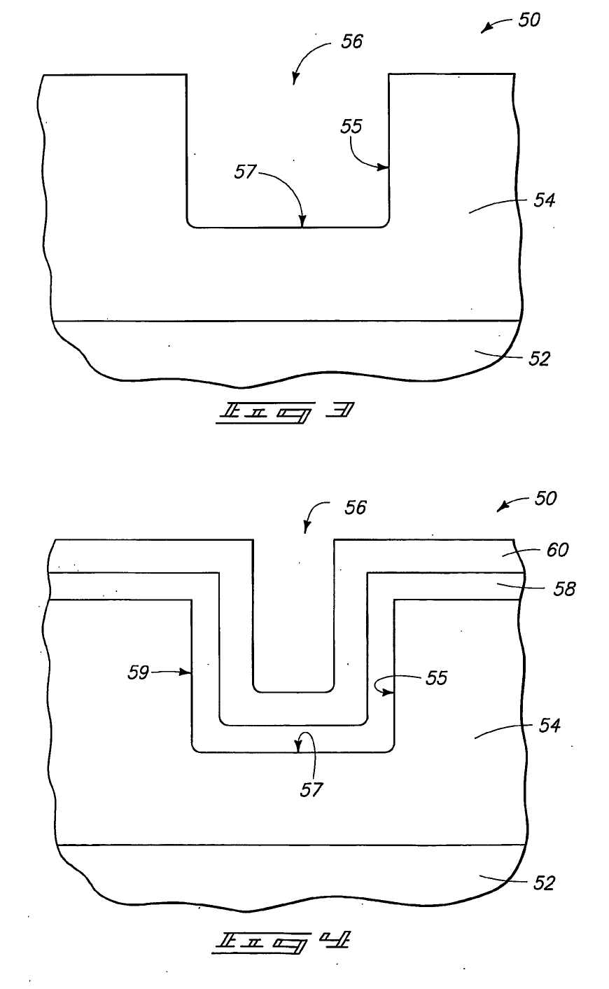

Exemplary embodiments of the present invention are described with reference to FIGS. 3-7. Referring initially to FIG. 3, a semiconductor wafer fragment 50 is illustrated. Wafer fragment 50 comprises a semiconductive material substrate 52, such as, for example, monocrystalline silicon. An insulative material 54 is formed over substrate 52, and an opening 56 is formed into insulative material 54. Materials 52 and 54 can comprise the same materials as described with reference to the prior art for materials 12 and 14, respectively. In particular applications, material 54 can comprise an organic or an inorganic low-k dielectric material having a k value of less than or equal to about 2.6. Examples of such materials having k values of less than or equal to about 2.6 include GX-3, HOSP, and NANOGLASS® E (Honeywell International. Inc., Morristown, N.J.), although the invention encompasses use of other dielectric materials having k values in this range.

Opening 56 can comprise, for example, a trench for formation of copper in a dual damascene process. Opening 56 can comprises a sidewall surface 55, and bottom surface 57. The dimensions of opening 56 are not limited to specific values. In particular applications, opening 56 can have a width of less or equal to about 350 nm and in some instances can be less than or equal to about 200 nm, or less than or equal to about 100 nm. Additionally, the aspect ratio (the ratio of the height relative to the width) of opening 56 is not limited to a particular value and can be, for example, greater than about 1. In some instances the aspect ratio can be greater than or equal to about 4.

Referring to FIG. 4, a barrier layer 58 is formed over insulative, layer 54 and within opening 56, and forms an interface 59 between insulative layer 54 and barrier layer 58. In accordance with the present invention, barrier layer 58 comprises titanium, and is configured to impede diffusion from subsequently-formed copper-based layers into insulative material 54. In one aspect of the invention, barrier layer 58 comprises titanium and one or more elements selected from the group consisting of Al, Ba, Be, Ca, Ce, Cs, Hf, La, Mg, Nd, Sc, Sr, Y, Mn, V, Si, Fe, Co, Ni, B, C, La, Pr, P, S, Sm, Gd, Dy, Zr, Ho, Er, Yb, W, Cr, Mo, Nb, and Ta. Further, barrier layer 58 can consist essentially of the titanium and one or more elements. Barrier layer 58 can also comprise one or both of nitrogen and oxygen in addition to the Ti and the one or more elements. Layer 58 can be considered as a film formed over substrate 54, and in particular embodiments can be considered as a liner of opening 56. Layer 58 will have a thickness of from about 2 nanometers to about 500 nanometers, and can specifically have a thickness of from about 2 nanometers to about 50 nanometers, or can specifically have a thickness of from about 2 nanometers to about 20 nanometers.

Factors that can be important in determining appropriate elements and atomic ratio of elements to form the titanium alloy materials of the present invention include: 1) differences in atomic size relative to Ti; 2) standard electrode potential of the element; and 3) melting temperature of the element. For example, a difference in atomic size can disrupt a titanium lattice structure, and accordingly impede grain growth within the lattice. A magnitude of difference in grain size between the titanium and the other elements incorporated into barrier layer 58 can affect the amount by which a lattice is disrupted, and accordingly can influence an amount of grain growth occurring at various temperatures. It can therefore be preferable in some instances, to utilize elements having larger differences in size relative to titanium than atoms having less difference in size relative to titanium.

In particular aspects of the invention, it can be advantageous to utilize one or more elements having a standard electrode potential of less than −1.0 V. Such elements can tend to diffuse toward interface regions of the barrier layer when exposed to thermal processing and thereby enhance the ability of the layer to inhibit or prevent diffusion into the barrier. Additionally, diffusion of the elements having a standard electrode potential of less than −1.0 V toward interface regions of the barrier layer can enhance the ability of the barrier layer to adhere to insulative materials. In some instances it can be advantageous to provide one or more elements having a melting temperature of greater than about 2400° C. to the alloy. Due to the refractory characteristics of elements having a melting temperature of greater than about 2400° C., inclusion of such elements can stabilize the titanium alloy.

In some applications, layer 58 can be a barrier for inhibiting or preventing diffusion from a metallic material to a non-metallic material. In an exemplary process, layer 58 is a barrier layer for preventing diffusion from a conductive copper-based. material to insulative material 54. In such embodiment, it can be preferred that barrier layer 58 be conductive to provide additional electron flow beyond that provided by the conductive copper-based layer. In such embodiments, it can be preferred that barrier layer 58 have an electrical resistivity of equal to or less than 300 μΩ·cm.

An exemplary method of forming barrier layer 58 is to sputter deposit layer 58 from a target comprising titanium and one or more elements. The one or more elements can be selected from the group consisting of Al, Ba, Be, Ca, Ce, Cs, Hf, La, Mg, Nd, Sc, Sr, Y, Mn, V, Si, Fe, Co, Ni, B, C, La, Pr, P, S, Sm, Gd, Dy, Zr, Ho, Er, Yb, W, Cr, Mo, Nb, and Ta. The invention encompasses deposition from a target that consists essentially of the titanium and the one or more elements. Also, the invention encompasses embodiments wherein the target consists of the titanium and the one or more elements.

An exemplary target can comprise at least 50 atom % titanium, and from 0.001 atom % to 50 atom % of the one or more elements selected from the group consisting of Al, Ba, Be, Ca, Ce, Cs, Hf, La, Mg, Nd, Sc, Sr, Y, Mn, V, Si, Fe, Co, Ni, B, C, La, Pr, P, S, Sm, Gd, Dy, Zr, Ho, Er, Yb, W, Cr, Mo, Nb, and Ta. In other embodiments, the target can comprise at least 90 atom % titanium, and from 0.001 atom % to 10 atom % of the one or more elements. The invention also encompasses utilization of targets having an atomic ratio of Ti to the one or more elements of less than 1.

In particular aspects of the present invention, the target utilized for forming barrier layer 58 will comprise zirconium. The ratio of titanium to zirconium comprised by the target is not limited to any particular value. Accordingly, Zr can be present in the target at from greater than 0 atomic percent to less than 100 atomic percent. In particular applications, the TiZr comprising target can also include one or more additional element selected from the group consisting of Al, Ba, Be, Ca, Ce, Cs, Hf, La, Mg, Nd, Sc, Sr, Y, Mn, V, Si, Fe, Co, Ni, B, C, La, Pr, P, S, Sm, Gd, Dy, Ho, Er, Yb, W, Cr, Mo, Nb, and Ta. In other embodiments, the TiZr target can consist essentially of Ti and Zr. The invention also encompasses utilization of TiZr targets consisting of Ti and Zr.

A target utilized in methodology of the present invention can be sputtered in an atmosphere such that only target materials are deposited in film 58, or alternatively can be sputtered in an atmosphere so that materials from the atmosphere are deposited in barrier layer 58 together with the materials from the target. For instance, the target can be sputtered in an atmosphere comprising a nitrogen-containing component to form a barrier layer 58 that comprises nitrogen in addition to the materials from the target. An exemplary nitrogen-containing component is diatomic nitrogen (N₂). The deposition atmosphere can, in some instances, additionally comprises Ar. The deposited thin film can be referred to by the stoichiometry (TiQ)ₓN_{z}, with “Q” being a label for the one or more elements selected from the group consisting of Al, Ba, Be, Ca, Ce, Cs, Hf, La, Mg, Nd, Sc, Sr, Y, Mn, V, Si, Fe, Co, Ni, B, C, La, Pr, P, S, Sm, Gd, Dy, Zr, Ho, Er, Yb, W, Cr, Mo, Nb, and Ta, that were incorporated into the target. In particular processing, the material (TiQ)ₓN_{z} will comprise x=0.40 to 0.60, and z=0.40 to 0.60. For example, where a target consisting essentially of titanium and zirconium is utilized for sputtering in an atmosphere comprising nitrogen, the resulting thin film can be (TiZr)_{0.40-0.60}N_{0.40-0.60}, and in particular embodiments will be (TiZr)_{0.47-0.6}N_{0.4-0.53}.

Another exemplary method of forming barrier layer 58 is to sputter deposit the layer from a target comprising titanium and one or more elements other than titanium in the presence of both a nitrogen-comprising component and an oxygen-comprising component, to incorporate both nitrogen and oxygen into barrier layer 58. Such processing can form a barrier layer having the stoichiometry TiₓQ_{y}N_{z}O_{w}, with Q again referring to the elements selected from the group consisting of Al, Ba, Be, Ca, Ce, Cs, Hf, La, Mg, Nd, Sc, Sr, Y, Mn, V, Si, Fe, Co, Ni, B, C, La, Pr, P, S, Sm, Gd, Dy, Zr, Ho, Er, Yb, W, Cr, Mo, Nb, and Ta. The compound TiₓQ_{y}N_{z}O_{w} can comprise, for example, x=0.1 to 0.7, y=0.001 to 0.3, z=0.1 to 0.6, and w=0.0001 to 0.0010. The oxygen-containing component used to form the TiₓQ_{y}N_{z}O_{w}, can be, for example O₂.

There can be advantages to incorporating nitrogen and/or oxygen into a barrier layer 58, in that such incorporation can improve the high-temperature stability of the barrier layer relative to its ability to exclude copper diffusion at high temperatures. The nitrogen and/or oxygen can, for example, disturb a Ti columnar grain structure and thus form a more equi-axed grain structure.

The electrically resistivity of barrier layer 58 can be influenced by deposition conditions during ablation of material from the target onto insulative material 54. An appropriate deposition power can depend upon the desired resistivity in layer 58, the particular composition of the deposition target and the deposition method and conditions utilized. Where layer 58 comprises (TiZr)ₓN_{z} an exemplary deposition power can be from about 1 kW to about 9 kW. For instance, in applications where layer 58 comprises (TiZr)ₓN_{z} formed utilizing a deposition power of about 2 kW, layer 58 can have a resistivity of about 69 μΩ·cm. Alternatively, the (TiZr)xN, layer can comprise a resistivity of about 106 μΩ·cm when formed at a deposition power of about 8.6 kW.

A barrier layer 58 formed in accordance with the present invention can comprise a mean grain size of less than or equal to 100 nanometers, and in particular processing can preferably comprise a mean grain size of less than or equal to 10 nanometers. More preferably, the barrier layer can comprise a mean grain size of less than 1 nanometer. Further, the barrier layer material can have sufficient stability so that the mean grain size remains less than or equal to 100 nanometers, and in particular embodiments less than or equal to 10 nanometers or 1 nanometer, after the film is exposed to 500° C. for 30 minutes in a vacuum anneal.

The small mean grain size of the film 58 of the present invention can enable the film to better preclude copper diffusion than can prior art titanium-containing films. Specifically, the prior art titanium-containing films frequently would form large grain sizes at processing above 450° C., and accordingly would have the columnar-type defects described above with reference to FIG. 2. Processing of the present invention can avoid formation of such defects, and accordingly can enable better titanium-containing diffusion layers to be formed than could be formed by prior art processing.

Where barrier layer 58 is deposited from a target comprising titanium and zirconium according to the present invention, layer 58 can comprise the same atomic ratio of titanium relative to zirconium as the target. Additionally, where additional metals are comprised by the target, layer 58 can have the same atomic ratio of the additional elements relative to the titanium and zirconium as was present in the target. Alternatively, barrier layer 58 can have an atomic ratio of titanium relative to the one or more additional elements that varies relative to the corresponding target. In particular aspects of the invention, barrier layer 58 can consist essentially of titanium, zirconium and nitrogen. In other embodiments, barrier layer 58 can consist of titanium, zirconium and nitrogen.

Barrier layer 58, formed in accordance with the present invention, can comprise non-columnar grains, or both non-columnar and columnar grains. In particular instances, non-columnar grains can be substantially equi-axed. In particular instances, barrier layer 58 can have a substantial absence of amorphous phase material.. Where barrier layer 58 comprises both non-columnar and columnar grains, the barrier layer can be described as having a thickness, a first portion of the thickness having non-columnar grains and a second portion of the thickness having a columnar grain microstructure. Where both non-columnar and columnar structures are present in barrier layer 58, the first portion comprising non-columnar grains is typically closer to interface 59 than is the second portion containing the columnar grain structure. Relative thickness of the first portion and second portion of layer 58 is not limited to a particular value. Additionally, it is to be understood that in particular instances a transition region may exist within the second portion which has both columnar and non-columnar grain structure.

An exemplary layer 58 comprising (TiZr)ₓN_{z} and having a thickness greater than about 5 nm can have a first portion that lacks columnar grain growth, the first portion being within the first 5 nm of interface 59, and can comprise a second portion having columnar grains, the second portion comprising the remaining portion of barrier layer 58 extending outward from the first portion. In an alternate example, where layer 58 has a thickness of greater than about 10 nm, the first portion that lacks columnar grains can be within the first 10 nm of interface 59 and the remaining portion extending outward from the first portion can comprise columnar grains. In another embodiment where barrier layer 58 comprises (TiZr)ₓN_{z} having a thickness of less than or equal to about 10 nm, the entire thickness of barrier layer 58 can consist of non-columnar grain structure.

Referring still to FIG. 4, a copper-containing seed layer 60 is formed over barrier layer 58. Copper-containing seed layer 60 can comprise, for example, high purity copper (i.e., copper which is at least 99.995% pure), and can be deposited by, for example, sputter deposition from a high purity copper target.

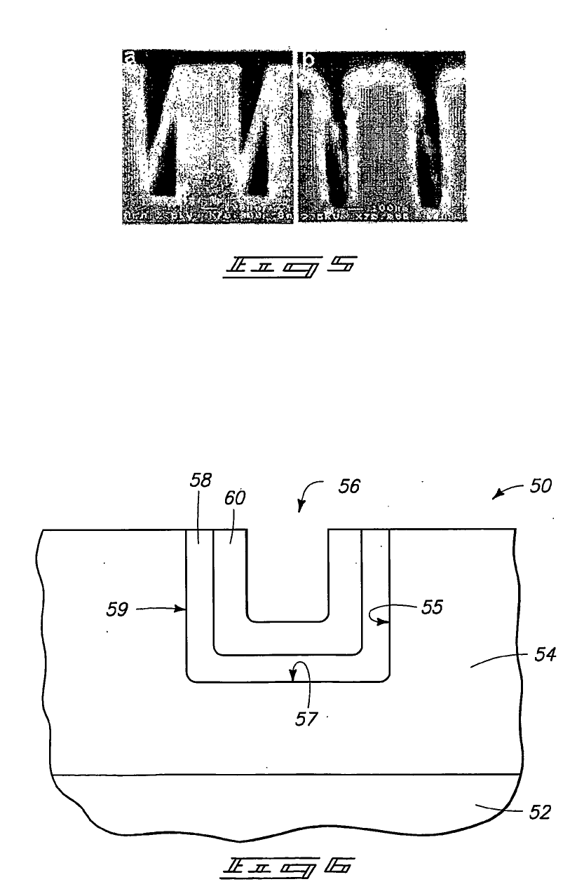

The titanium materials of the present invention can provide substantially uniform step coverage suitable for lining gap structures such as those utilized in copper dual damascene integration. Accordingly, titanium materials according to the present invention can be utilized where opening 56 has a high aspect ratio, where the aspect ratio refers to the ratio of the opening height (a length of sidewall 55) relative to the opening width (the length of bottom surface 57). FIG. 5 illustrates the step coverage for an opening having an aspect ratio of 4:1 (200 nm wide×800 nm high). The figure shows a (TiZr)ₓN_{z} barrier liner before (Panel A) and after (Panel B) deposition of the copper seed layer. The substrate utilized in forming the structure shown in FIG. 5 contains 200 nm wide gap structures etched in SiO₂. The resulting barrier layer and copper seed layer where each observed to be smooth and of uniform thickness.

FIG. 6 illustrates wafer fragment 50 after it has been exposed to chemical-mechanical polishing (CMP) to remove layers 58 and 60 from over an upper surface of insulative material 54 while leaving materials 58 and 60 within trench 56. CMP of a (TiZr)ₓN_{z} layer over a SiO₂ coating resulted in a mirror-quality surface finish which, when examined by SEM showed no discernable scratches on the entire surface of the film (not shown). Additionally, no delamination of the (TiZr)ₓN_{z} film occurred during CMP.

Additional processing that can occur after formation of seed layer 60 includes thermal processing. The thermal processing can comprise, for example, an anneal at a temperature of from about 100° C. to about 300° C., for about 30 minutes, under vacuum. Where the titanium alloy comprises one or more elements having a standard electrode potential of less than −1.0V, it can be advantageous to expose layer 58 to thermal processing in order to diffuse the elements having a standard electrode potential of less than −1.0V to the barrier interfaces, as discussed above.

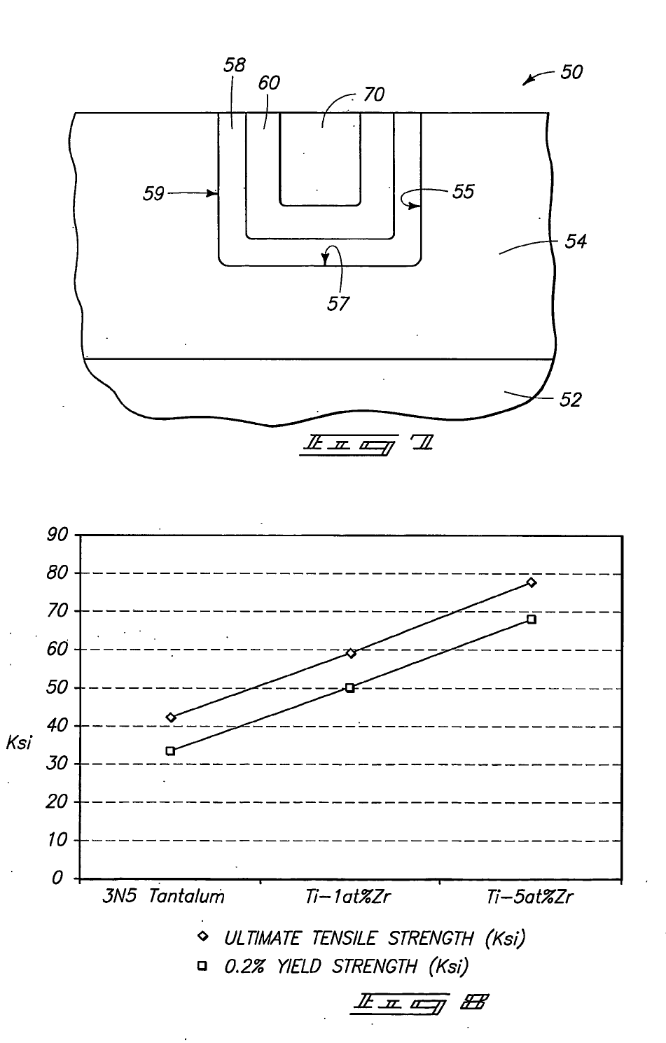

FIG. 7 illustrates wafer fragment 50 at a processing step subsequent to that of FIG. 6, and specifically shows a copper-based material 70 formed within trench 56 (FIG. 6). Copper-based material 70 can be formed by, for example, electrodeposition of copper onto seed layer 60. An advantage of having a conductive barrier layer 58 is evidenced in FIG. 7. Specifically, as trenches become increasingly smaller, the amount of the trench made smaller by barrier layer 58 relative to that consumed by copper material 70 can increase. Accordingly, layers 58, 60 and 70 can be considered a conductive component, with layer 58 having an increasingly larger representative volume as trench sizes become smaller. A reason that layer 58 can have an increasingly larger volume is that there are limits relative to the thickness of layer 58 desired to maintain suitable copper-diffusion barrier characteristics. As the relative volume of layer 58 increases within the conductive component comprising layers 58, 60 and material 70, it can be desired to have good conductive characteristics within material 58 to retain good conductive characteristics within the conductive component.

Barrier layer 58 formed utilizing titanium materials according to the present invention allows the resistance contribution of barrier layer 58 to be low relative to conventional TaN barrier layers. For example, in a copper filled via having dimensions of 100 nm×100 nm, a 10 nm thick bottom barrier/liner of TaN deposited at 8.6 kW would have a via resistance contribution from the TaN barrier/liner of approximately 2.54 Ω. The corresponding (TiZr)ₓN_{z} liner having identical dimensions to the TaN liner would have a via resistance contribution of approximately 0.69 Ω. Corresponding liners deposited at 2 kW would have a via resistance contribution of 22.8 Ω for the TaN liner and approximately 1.06 Ω for the (TiZr)ₓN_{z} liner.

Materials formed in accordance with the present invention can have suitable mechanical properties for barrier layer applications. FIG. 8 shows that materials formed in accordance with the present invention can have mechanical properties equal to, or better than, those of 3N5 tantalum, with the mechanical properties of FIG. 8 being reported in units of Ksi (i.e, 1000 lbs/in²).

### EXAMPLES

The invention is illustrated by, but not limited to, the following examples. The examples describe exemplary methodologies for forming thin films comprising various materials encompassed by the present invention.

### Example 1

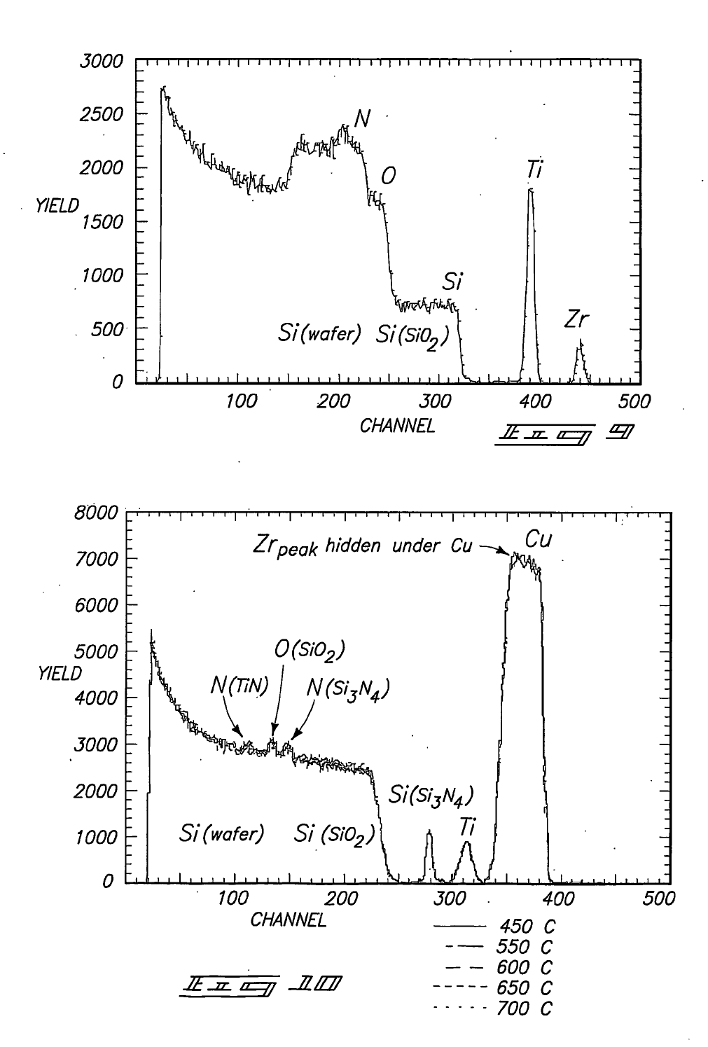

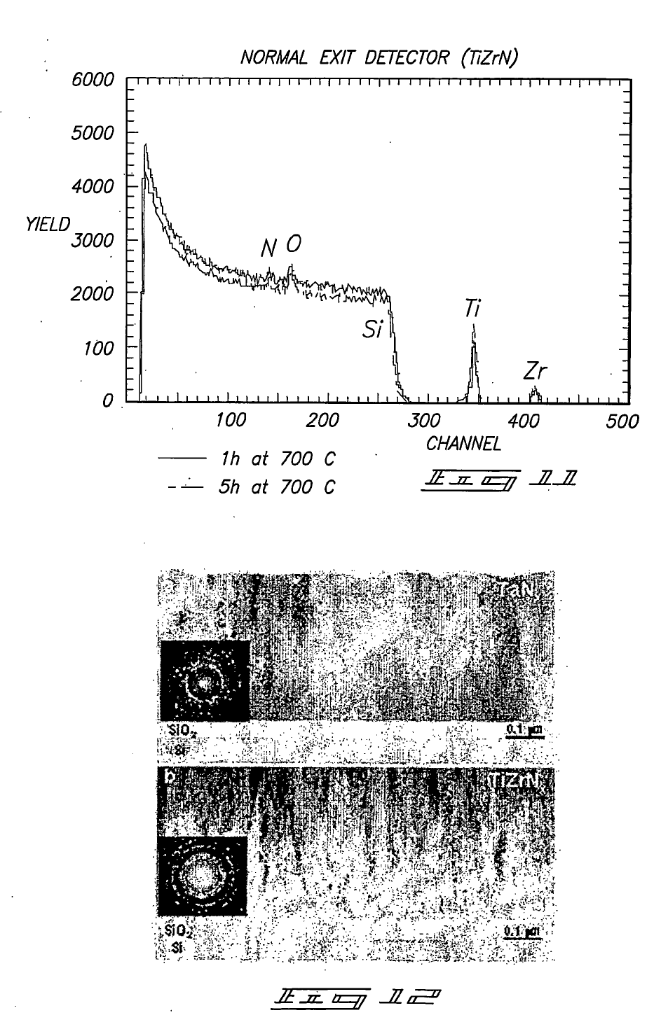

A TiZr target comprising 5.0 at % Zr was reactively sputtered in a N₂/Ar atmosphere. The resulting TiZrN thin film had a thickness of approximately 20 nm and an electrical resistivity of approximately 125 μΩ·cm. Transmission electron microscopy (TEM) examination of the TiZrN film showed extremely small crystallites (<5 nm at the SiO₂ interface), which could. not be measured by X-ray, and which were stable after vacuum annealing at 700° C. for 5 hours. A 150 nm Cu film was then deposited onto the TiZrN film so that diffusional properties of the TiZrN film could be tested after annealing at high temperature. Results indicate that the TiZrN film had good adhesion to intermetallic dielectrics and wetting characteristics with Cu. The thin film had overall properties that are adequate for a typical Cu/low-k dielectric process. FIG. 9 shows the Rutherford Back-scattering Spectroscopy (RBS) profile of as-deposited Ti_{0.45}zr_{0.024}N_{0.52}; and Table 1 tabulates various aspects of the data of FIG. 9. FIG. 10 illustrates that there is no apparent diffusion of Cu into the TiZrN layer after vacuum annealing at about 450° C.-700° C. for 1 hour. FIG. 11 shows the RBS profile of the TiZrN film after the Cu layer has been stripped from the wafer. This figure again shows no apparent diffusion of Cu into the TiZrN layer after 5 hours at 700° C.

Similar studies performed on a TiZr layer (deposited in an absence of added nitrogen) indicated a similar absence of copper diffusion after heat treatment for one hour at 550° C.

TABLE 1
RBS determined film composition in atomic percent

| | Thickness | | | | | |
|---|---|---|---|---|---|---|
| Film | (nm) | Si | O | Ti | N | Zr |
| TiZrN | 20 | 0 | 0 | 0.45 | 0.526 | 0.024 |
| SiO₂ | 300 | 0.334 | 0.666 | 0 | 0 | 0 |
| Si | wafer | 1 | 0 | 0 | 0 | 0 |

### Example 2

(TiZr)ₓN_{z} films were deposited by reactive physical vapor deposition (PVD) onto a SiO₂ coated silicon wafer, at a base chamber pressure of approximately. 10⁻⁸ Torr in an Ar/N2 plasma at approximately 5 mTorr. Film deposition was performed at a temperature of about 400° C., at a power of about 6.5 kW. RBS analysis indicated that the resulting layer had a Zr to Ti ratio which matched the Zr to Ti ratio of the deposition target, and indicated a metal (TiZr) to nitrogen ratio of (TiZr)_{0.47-0.6}N_{0.53-0.04}. The variable measurement obtained for the N content of the (TiZr)ₓN_{z} layer may possibly be due to fluctuation in the N₂ pressure during the deposition, and may additionally reflect resolution limit of the RBS analysis (+5% for N).

For comparison purposes, TaN films were prepared using deposition conditions as set forth above for the (TiZr)ₓN_{z} layer formation. The amount of N incorporated into the TaN layers was found to be more varied relative to the (TiZr)ₓN_{z} layers, with RBS analysis indicating Ta to N ratios of Ta_{0.6-0.4}N_{0.4-0.6}. The larger variation in the amount of nitrogen incorporated into the TaN films may potentially be due to the presence of both amorphous and crystalline phases in the TaN films.

FIG. 12 shows transmission electron microscopy (TEM) comparison between the microstructures of a TaN film (Panel A) and a (TiZr)ₓN_{z} film (Panel B). The TEM images of (TiZr)ₓN_{z} layers reveal non-columnar microstructure within the fist 10 nm from the SiO₂, with columnar grains observed in regions of the layer beyond the first 10 nm from the SiO₂. The non-columnar microstructure comprises thin, equi-axed grains. The columnar microstructure has column diameters in the range of from about 10 nm to about 20 nm. Selected area diffraction (SAD) pattern of the (TiZr)ₓN_{z} columns (Panel B; inset) indicated crystalline material having NaCl (B1) type f.c.c structure.

In contrast, the TEM images of TaN layers indicate smaller grains which appear to be imbedded as part of a mixture of amorphous and crystalline phase material near the SiO₂ interface. (Additional TaN layers formed at varied deposition powers (not shown) revealed that the fraction of amorphous material increases with decreasing deposition power.) At increased distance from the SiO₂ interface, the TaN layer contained columnar structure having larger column diameters relative to those observed in the (TiZr)ₓN_{z} layers. The SAD pattern for TaN layers (Panel A; inset) reveals a poorly defined ring indicative of h.c.p crystal structure.

### Example 3

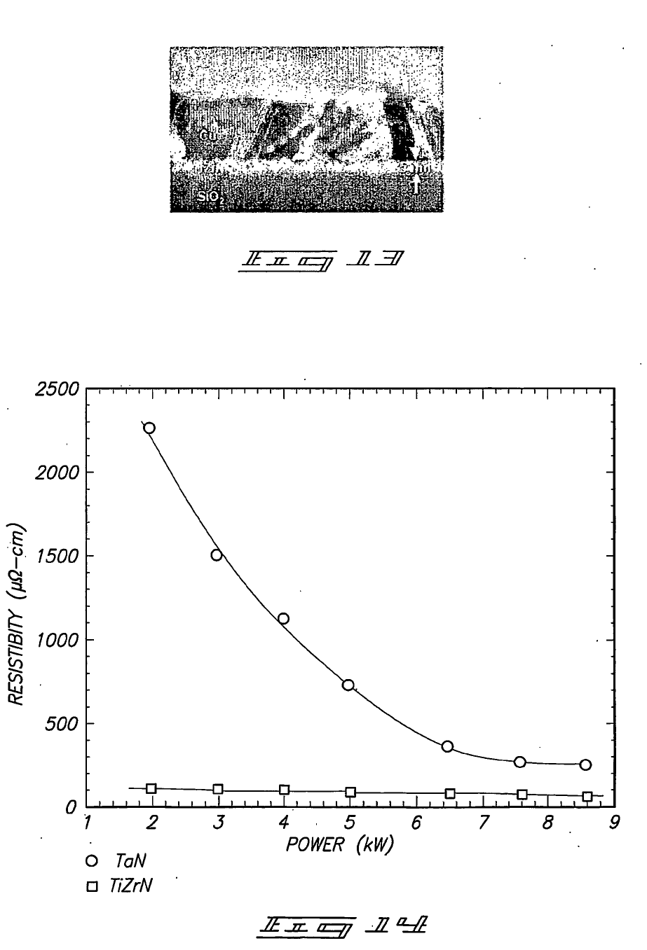

The barrier strength and film stability of (TiZr)xN, layers as thin as 5 nm were analyzed. A 5 nm (TiZr)ₓN_{z} film was formed utilizing the deposition conditions set forth in Example 2, above. Subsequent to the deposition of the film layer, copper was deposited over the barrier film. Copper deposition was conducted at a temperature of about 350° C., at a power of 2 kW, in the presence of Ar gas. Chemical vapor deposition was utilized to deposit a Si₃N₄ capping layer over the copper. RBS (not shown) and TEM analysis revealed no indication of any copper diffusion through the 5 nm layer after 1 hour at 650° C. FIG. 13 shows a TEM image of the microstructure of a cross-section of the 5 nm (TiZr)ₓN_{z} film after 1 hour at 650° C. There is no indication in this figure of any copper diffusion or secondary phase formation with copper.

### Example 4

Adhesion of (TiZr)ₓN_{z} layers was also analyzed and compared to TaN layers. Stud-pull tests were conducted utilizing Si/SiO₂/(TiZr)ₓN_{z}/Cu/Si₃N₄ stacks and Si/SiO₂/TaN/Cu/Si₃N₄ stacks formed utilizing the conditions set forth in Examples 2 and 3, above. Average stud-pull strength measurements of about 900 MPa were obtained for both the (TiZr)ₓN_{z} and the TaN.

Peel adhesion tests utilizing the Standard Tape Test Method were conducted to determine (TiZr)ₓN_{z} adhesion to low-k dielectric materials. Stacks were formed as above with the exception that the SiO₂ layer was substituted with an approximately 600 nm layer of low-k dielectric material having a k value of less than or equal to about 2.6. Analysis included comparison between stacks having (TiZr)ₓN_{z} disposed between the copper and the dielectric, and stacks without having a layer interposed between the copper and the dielectric. The results of the peel test utilizing three different low-k dielectric materials are summarized in Table 2.

The observed adhesion of the (TiZr)ₓN_{z} to the dielectric materials was maximal when degassing was conducted prior to deposition of the (TiZr)ₓN_{z} layer. As shown in Table 2, (TiZr)ₓN_{z} adheres well to the tested dielectric materials.

TABLE 2
Peel Test Adhesion

| | | | dielectric/ | dielectric/ |
|---|---|---|---|---|
| | Dielectric | | (TiZr)ₓN_{z} | copper |
| Dielectric material | type | K value | interface | interface |
| GX-3 | Organic | 2.6 | Pass | Pass |
| HOSP | Inorganic | 2.5 | No data | Pass |
| NANOGLASS ® E | Inorganic | 2.2 | Pass | Fail |

### Example 5

The electrical resistivity of (TiZr)ₓN_{z} films deposited over a range of deposition power was analyzed and compared to resistivity properties of TaN films. Both the TaN films and the (TiZr)ₓN_{z} films were deposited at a deposition temperature of about 400° C. in an Ar/N₂ plasma at a deposition gas pressure of from about 2-5 mTorr. Sheet resistance (Rₛ) was measured by the 4point probe method. Bulk electrical resistivity (ρ=Rₛt) was determined by measuring the film thickness (t) using SEM, TEM and profilometery. The specific gravity of deposited films was determined from the weight and thickness of the film.

FIG. 14 depicts the resistivity values of films as a function of deposition powers over a power range of from about 2 kW to about 8.6 kW. Both the TaN and the (TiZr)ₓN_{z} films exhibited decreased resistivity with increasing deposition power. However, the resistivity of (TiZr)ₓN_{z} films was consistently lower than that of TaN films deposited at the corresponding deposition power. Additionally, the resistivity of the (TiZr)ₓN_{z} varied to a much lesser extent relative to TaN, with a resistivity of about 106 μΩ·cm at a deposition power of about 2 kW, and a resistivity of about 69 μΩ·cm for a film deposited at about 8.6 kW. The TaN films exhibit increased film density with increasing deposition power but contained significant fractions of amorphous microstructure at the lower end of the range of deposition power. In contrast, the (TiZr)ₓN_{z} films had pronounced crystalline structure and dense atomic packing at all deposition powers.

In addition to the embodiments described above having barriers comprising a single TiQ or (TiQ)ₓN_{z} material, barrier layers according to the present invention can comprise a combination of materials. For example, for a barrier layer having a thickness, a first portion of the thickness can comprise a first material and a second portion of the thickness can comprise a second material. In some applications the first portion can comprise a first atomic percent nitrogen while the second portion contains a different atomic percent nitrogen, or a substantial absence of nitrogen. The invention also encompasses barrier layers having a third portion of the thickness of the layer that comprises a third material that differs relative to at least one of the first and second materials. A difference in nitrogen concentrations, a range of nitrogen concentrations or a nitrogen concentration gradient can be incorporated into the barrier layer by appropriately altering the nitrogen atmosphere during deposition of the barrier layer. A material substantially free of nitrogen can be deposited utilizing a deposition atmosphere that lacks added nitrogen.

Referring again to FIG. 7, an exemplary barrier layer 58 can be a bi-layer having a first portion that comprises TiZr and a second portion comprising,(TiZr)ₓN_{z} with x and y having values as described above. In particular applications it can be advantageous to provide barrier layer 58 as a bi-layer to enhance or maximize adhesion of the barrier to the adjacent interface materials such as underlying non-metallic material 54 and overlying metallic material 60. TiZr has enhanced adhesion to materials such as copper materials relative to (TiZr)ₓN_{z} . However, (TiZr)ₓN_{z} adheres better toSiO₂ than does TiZr. Accordingly, it can be advantageous to provide a barrier bi-layer having a (TiZr)ₓN_{z} portion adjacent SiO₂ interface 59, and a TiZr portion adjacent the interface between barrier 58 and copper material 60.

The relative thickness of the TiZr portion and the (TiZr)ₓN_{z} portion of a barrier bi-layer are not limited to any particular value or range of values. Accordingly, the invention contemplates a TiZr/(TiZr)ₓN_{z} bi-layer having a TiZr portion of the barrier thickness of from greater than zero % to less than 100%. The invention similarly contemplates all proportional ranges of TiZr/(TiZr)ₓN_{z}/TiZr barriers and (TiZr)ₓN_{z}/TiZr/(TiZr)ₓN_{z} layers. Where alternative materials are utilized for material 54 and 60, appropriate barrier materials can be determined by considering the adhesion properties of the interfacing materials, in combination with the resistivity and strength properties desired for the particular barrier application.

It is to be understood that the invention also contemplates barrier layers comprising combinations of other Ti alloys. Alternatively described, barrier 58 can comprise various combinations and thicknesses of any of the TiQ, (TiQ)ₓN_{z} and TiₓQ_{y}N_{z}O_{w}, materials set forth above.

The embodiments described herein are exemplary embodiments, and it is to be understood that the invention encompasses embodiments beyond those specifically described. For instance, the chemical-mechanical polishing described as occurring between the steps of FIGS. 4 and 6, could instead be conducted after electrodeposition of the copper material 70 that is shown in FIG. 7. Also, the anneal described with reference to FIG. 6 could be conducted instead after the processing of FIG. 7.

The titanium alloys of the present invention can be utilized to protect materials and surfaces in, for example, microelectronic devices. The results of the studies conducted on (TiZr)ₓN_{z} indicated that (TiZr)ₓN_{z} can be effectively used as a copper barrier in metal interconnect technology. Due to the comparable or superior properties of (TiZr)ₓN_{z} relative to TaN materials, the (TiZr)ₓN_{z} materials and films of the present invention may be particularly suitable as alternative to TaN in other microelectronic applications and in other technologies as well. Additionally, although various aspects of the invention are described with reference to creating barrier layers to alleviate copper diffusion, it is to be understood that the methodology described herein can be utilized for creating barrier layers that impede or prevent diffusion of metals other than copper; such as, for example, Ag, Al, Sn and Mg.

1. A thin film consisting essentially of Zr, N and optionally Ti, at least a portion of the thin film having a non-columnar grain structure.

2. The thin film of claim 1 having a thickness of less than or equal to about 10 nm.

3. The thin film of claim 1 having a thickness, wherein a first portion of the thickness comprises the non-columnar grain structure and wherein a second portion of the thickness comprises columnar grains.

4. The thin film of claim 3 wherein the columnar grains have diameters of from about 10 nm to about 20 nm.

5. The thin film of claim 3 wherein the thin film is disposed over a silicon dioxide surface and wherein the first portion of the thickness is disposed closer to the silicon dioxide surface than is the second portion.

6. The thin film of claim 1 having an atomic ratio of Ti to Zr greater than or equal to 1.0.

7. The thin film of claim 5 consisting essentially of Ti, Zr and N.

8. The thin film of claim 1 wherein the N is present in the thin film at from about 40 atomic percent to about 60 atomic percent.

9. The thin film of claim 1 having a resistivity of from about 69 μΩ·cm to about 106 μΩ·cm.

10. A barrier layer comprising Ti and Zr, a first portion of the barrier layer comprising a non-columnar grain structure, and a second portion of the layer comprising columnar grain structure.

11. The barrier layer of claim 10 further comprising one or more elements selected from the group consisting of Al, Ba, Be, Ca, Ce, Cs, Hf, La, Mg, Nd, Sc, Sr, Y, Mn, V, Si, Fe, Co, Ni, B, C, La, Pr, P, S, Sm, Gd, Dy, Ho, Er, Yb, W, Cr, Mo, Nb, and Ta.

12. The barrier layer of claim 10 disposed between a metallic material and a non-metallic material.

13. The barrier layer of claim 12 wherein the non-metallic material comprises a member of the group consisting of SiO₂ and low-k dielectric materials.

14. The barrier layer of claim 12 wherein the metallic layer comprises copper.

15. The barrier layer of claim 13 having a thickness of from about 10 nm to about 20 nm, wherein the first portion of the layer is closer to the non-metallic material than is the second portion.

16. A metal diffusion barrier comprising:
a first layer comprising Ti and Q and being substantially nitrogen free, where Q comprises one or more elements selected from the group consisting of Al, Ba, Be, Ca, Ce, Cs, Hf, La, Mg, Nd, Sc, Sr, Y, Mn, V, Si, Fe, Co, Ni, B, C, La, Pr, P, S, Sm, Gd, Dy, Ho, Er, Yb, W, Zr, Cr, Mo, Nb, and Ta; and
a second layer comprising (TiQ)ₓN_{z}.

17. The metal diffusion barrier of claim 16 wherein Q comprises Zr.

18. The metal diffusion barrier of claim 16 wherein the second layer is over the first layer, and further comprising a third layer over the second layer, the third layer comprising Ti and Zr and being essentially free of nitrogen.

19. The metal diffusion barrier of claim 16 wherein the first layer is over the second layer, and further comprising a third layer over the first layer, the third layer comprising (TiQ)ₓN_{z}.

20. The metal diffusion barrier of claim 16 disposed between a metallic material and a non-metallic material.

21. A copper diffusion barrier comprising a bi-layer, a first portion of the bi-layer comprising TiZr, and a second portion of the bi-layer comprising (TiZr)ₓN_{z}.

22. The copper diffusion barrier of claim 21 wherein the second portion comprises non-columnar grain structure.

23. The copper diffusion barrier of claim 21 wherein the second portion is adjacent a layer of silicon dioxide and the first portion is adjacent a copper based material.

24. A titanium-comprising material having an electrical resistivity of from about 69 μΩ·cm to about 106 μΩ·cm, and having a substantially uniform thickness.

25. The titanium-comprising material of claim 24 further comprising Zr.

26. The titanium-comprising material of claim 25 having an atomic ratio of Ti to Zr of greater than or equal to 1, and further comprising from about 40 atomic percent to about 60 atomic percent N.

27. The titanium-comprising material of claim 24 further comprising N.

28. A copper barrier film having a first portion comprising a non-columnar grain structure, and a second portion comprising a columnar grain structure, the film having a substantial absence of amorphous phase material.

29. The film of claim 28 comprising Ti.

30. The film of claim 28 comprising Zr.

31. The film of claim 28 comprising Ti, Zr and N.

32. The film of claim 28 consisting essentially of (TiZr)ₓN_{z}, where x=0.40-0.60 and z=0.40-0.60.

33. The film of claim 18 having an electrical resistivity of from about 69 μΩ·cm to about 106 μΩ·cm.

34. The film of claim 28 having a thickness of less than 20 nm.

35. A diffusion protected surface comprising:
a material having a surface; and
a thin film consisting essentially of Zr and N and optionally Ti over the surface, at least a portion of the thin film having a non-columnar grain structure.

36. The diffusion protected surface of claim 35 wherein the thin film comprises Ti.

37. The diffusion protected surface of claim 35 wherein the material having the surface comprises a non-metallic material.

38. The diffusion protected surface of claim 35 wherein the material having the surface comprises SiO₂.

39. The diffusion protected surface of claim 35 wherein the thin film is disposed between the surface and a metallic material comprising one or more of Cu, Ag, Sn, Mg and Al.

40. A structure comprising:
a silicon substrate;
a insulative material over the substrate;
a barrier layer consisting essentially of (TiZr)ₓN_{z} over the insulative material, the barrier layer having a substantial absence of amorphous structure, at least a portion of the barrier layer comprising non-columnar grain structure; and
a layer comprising a metal over the barrier layer.

41. The structure of claim 40 wherein x=0.44-0.60 and z=0.40-0.60.

42. The structure of claim 40 wherein the metal comprises copper.

43. The structure of claim 40 wherein the metal comprises copper, wherein the insulative material comprises SiO₂; wherein the barrier layer has a thickness of less than or equal to about 5 nm; and wherein, the barrier layer substantially prevents diffusion of copper from the layer comprising the metal into the SiO₂ during heat treatment of the structure at a temperature of about 650° C. for about 1 hour.

44. The structure of claim 40 wherein the metal comprises copper, wherein the insulative material comprises SiO₂; wherein the barrier layer has a thickness of less than or equal to about 20 nm; and wherein, the barrier layer substantially prevents diffusion of copper from the layer comprising the metal into the SiO₂ during heat treatment of the structure at a temperature of about 700° C. for about 5 hours.

45. A microelectronic device comprising:
a insulative material comprising an opening having a bottom surface and a sidewall surface;
a barrier layer over the bottom surface, the barrier layer comprising Ti and Zr, and having an electrical resistivity of less than or equal to about 69 μΩ·cm to about 106 μΩ·cm; and
a material comprising copper disposed over the barrier layer.

46. The microelectronic device of claim 45 wherein the opening has a width of less than or equal to about 350 nm.

47. The microelectronic device of claim 45 wherein the opening has a width of less than or equal to about 100 nm.

48. The microelectronic device of claim 45 wherein the barrier layer is disposed over the sidewall surface.

49. The microelectronic device of claim 48 wherein the barrier layer has a substantially uniform thickness over the bottom surface and over the sidewall surface.

50. The microelectronic device of claim 49 wherein the opening has a height to width aspect ratio of greater than or equal to 1.

51. The microelectronic device of claim 50 wherein the aspect ratio is greater than 2.

52. The microelectronic devise of claim 49 wherein thickness is less than or equal to about 20 nm.

53. The microelectronic devise of claim 49 wherein thickness is less than or equal to about 5 nm.

54. The microelectronic devise of claim 45 wherein the barrier layer comprises an atomic ratio of Ti to Zr of greater than or equal to 1.0.

55. The microelectronic devise of claim 45 wherein the barrier layer further comprises N.

56. The microelectronic device of claim 55 wherein the barrier layer comprises from about 40 atomic percent to about 60 atomic percent N.

57. The microelectronic device of claim 55 wherein the barrier layer consists essentially of Ti, Zr and N.

58. The microelectronic device of claim 55 wherein the barrier layer consists of Ti, Zr, and N.

59. The microelectronic device of claim 45 wherein the material comprising copper consists essentially of copper.

60. A method of forming a barrier layer comprising:
providing a substrate comprising a material to be protected;
providing a target comprising Ti and Zr; and
in the presence of an Ar/N₂ plasma, ablating material from the target onto the substrate at a deposition power of from about 2 kW to about 9 kW, the ablating forming a barrier layer comprising Ti, Zr and N and having a substantially uniform thickness over at least a portion of the material to be protected.

61. The method of claim 60 wherein the target consists essentially of Ti and Zr.

62. The method of claim 60 wherein the barrier layer has an atomic ratio of Ti to Zr of greater than or equal to about 1.

63. The method of claim 60 wherein the barrier layer has an electrical resistivity of from about 69 μΩ·cm to about 106 μΩ·cm.

64. The method of claim 60 further comprising depositing a conductive material over the barrier layer, the conductive material comprising a metal.

65. A method of forming a microelectronic device, comprising:
providing a substrate having one or more gap structures formed in an insulative material;
lining the gap structures with a layer comprising Ti, the layer having a substantially uniform thickness and having an electrical resistivity of from about 69 μΩ·cm to about 106 μΩ·cm;
depositing a copper material over the layer.

66. The method of claim 65 wherein the layer further comprises N and one or more elements selected from the group consisting of Al, Ba, Be, Ca, Ce, Cs, Hf, La, Mg, Nd, Sc, Sr, Y, Mn, V, Si, Fe, Co, Ni, B, C, La, Pr, P, S, Sm, Gd, Dy, Zr, Ho, Er, Yb, W, Cr, Mo, Nb, and Ta.

67. The method of claim 66 wherein the layer consists essentially of Ti, Zr and N.

68. The method of claim 65 wherein the one or more gap structures comprise openings having a height to width aspect ratio of greater than or equal to 4.

69. The method of claim 68 wherein the openings have a width of less than or equal to about 350 nm.

70. The method of claim 68 wherein the openings have a width of less than or equal to about 200 nm.

71. The method of claim 68 wherein the openings have a width of less than or equal to about 100 nm.

72. The method of claim 65 wherein the insulative material comprises SiO₂.

73. A method of forming a protected surface comprising:
providing a substrate having a surface into a reaction chamber;
providing a target within the reaction chamber, the target consisting essentially of Ti and Zr;
ablating material from the target onto the surface in the presence of nitrogen to deposit a first layer over the surface; and
ablating material from the target in an absence of added nitrogen to form a second layer over the first layer.

74. The method of claim 73 wherein the surface comprises silicon dioxide.

75. The method of claim 73 wherein the first layer has a thickness of less than or equal to about 10 nm, and has a microstructure consisting essentially of non-columnar grains.

76. The method of claim 73 wherein the first layer has a thickness of greater than about 10 nm, and comprises a first portion having non-columnar grain structure and a second portion comprising columnar grain structure.
